(19) United States
(12) Patent Application Publication
(10) Pub. No.: US 2007/0026324 A1
(43) Pub. Date: Feb. 1, 2007

(54) Substrate with light-shielding film, color filter substrate, method of manufacture of both, and display device having substrate with light-shielding film

(75) Inventors: Takuji Yoshida, Kumamoto (JP); Hatsumi Kimura, Kumamoto (JP); Nobuaki Ishiga, Kumamoto (JP); Takahito Yamabe, Kumamoto (JP); Toshio Araki, Kumamoto (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/484,606

(22) Filed: Jul. 12, 2006

(30) Foreign Application Priority Data
Jul. 28, 2005 (JP) 2005-218152
May 1, 2006 (JP) 2006-127403

(51) Int. Cl. G03F 1/00; G03F 1/08

(52) U.S. Cl. 430/7; 430/5; 430/321; 430/322

(57) ABSTRACT

A substrate with a light-shielding film according to one mode of the invention is obtained in a method of manufacture of a substrate with a light-shielding film having a light-shielding film pattern formed on a substrate, by depositing in order a first film having chromium oxide and a second film having chromium on a substrate, to form a multilayer film; forming a resist pattern on the multilayer film; performing etching of the multilayer film, using an etching liquid comprising ceric ammonium nitrate to which nitric acid is added at a concentration of at least 2.5 mol/liter, to form a light-shielding film pattern; and removing the resist pattern.

### BACKGROUND OF THE INVENTION

1. Field of the Invention

This invention relates to a substrate with a light-shielding film, a color filter substrate, and a method of manufacture of both of these, as well as to a display device comprising a substrate with a light-shielding film. More particularly, this invention relates to a substrate with a light-shielding film having at least a chromium oxide, to a color filter substrate and to a method of manufacture of both of these, as well as to a display device comprising a substrate with a light-shielding film.

2. Description of the Related Art

In recent years in the field of image display devices, liquid crystal displays, electroluminescence (EL) display devices, plasma display panels, and other flat panel displays are rapidly spreading and displacing CRT displays. Normally a light-shielding film is provided between the display pixels in such display devices. The light-shielding film has a function of shielding or blocking unnecessary light between the display pixels. By this means, the contrast ratio of images is improved, and display quality can be enhanced. For example, a light-shielding film is formed between the color layers of the color filter substrate in a liquid crystal display device.

Normally a chromium film, with high opacity, is used in the light-shielding film. When etching a light-shielding film based on a chromium film, a method is widely known in which a liquid chemical, the principal components of which are ceric ammonium nitrate and perchloric acid, is used (see Kiyotaka Naraoka and Kimiyuki Nihei, Photoetching and Fine Processing, Sougou Denshi Shuppansha, published May 1977). As a method of etching a chromium film, a method has been disclosed which uses an etching liquid comprising, at least, ceric ammonium nitrate, nitric acid, perchloric acid, and water (see Japanese Unexamined Patent Application Publication No. 10-46367, paragraph 0010). In this reference, etching is performed with the nitric acid concentration at from 1 to 2 mol/liter, and with the perchloric acid concentration at 1 mol/liter or above. By this means, a chromium film can be etched to a tapered shape.

Further, a light-shielding film for a display device, with a multilayer structure of chromium film and chromium nitride film, has been disclosed (see Japanese Unexamined Patent Application Publication No. 6-250163, paragraphs 0009-0011). In this reference, etching is performed using as the etching liquid a mixed solution of ceric ammonium nitrate and perchloric acid. The etching rate of the chromium nitride film using the above etching liquid is slower than the etching rate for chromium film. As a result, the pattern of the light-shielding film can be etched to a tapered shape. Moreover, in this reference the nitrogen gas partial pressure in the argon gas is gradually raised during sputter deposition of the chromium nitride film. By this means, the degree of nitrification of the chromium nitride film can be changed in the film thickness direction. Because the degree of nitrification is increased in the vicinity of the surface of the light-shielding film, a cross-sectional shape with a satisfactory tapered shape can be obtained.

In addition, a multilayer film, obtained by forming in succession, on a transparent substrate, a chromium oxide (CrOₓ, where x is a positive number) film having low reflectivity characteristics and a chromium (Cr) film having high opacity characteristics, and used as a light-shielding film, has been disclosed (Japanese Unexamined Patent Application Publication No. 11-194333, paragraph 0003; Japanese Unexamined Patent Application Publication No. 2004-54228). By means of this configuration, a light-shielding film can be provided with low reflectivity characteristics to prevent unwanted reflection of light and the high opacity characteristics to prevent unwanted transmission of light. Further, in place of a chromium film to shield light, a CrNₓ (where x is a positive number) film with nitrogen (N) added to increase the density of the crystal texture and improve the light-shielding characteristics, can be used. In this way, Cr/CrOₓ multilayer structures, and CrNₓ/CrOₓ multilayer structures, are used as light-shielding films.

As disclosed in Japanese Unexamined Patent Application Publication No. 11-194333, it is known that when etching a Cr/CrOₓ multilayer structure, there is the problem of occurrence of a reverse-taper shape. That is, the etching rates are different for a CrOₓ film and for a Cr film (or for a CrNₓ film). Consequently the etching end face assumes a discontinuous shape, or assumes a reverse-taper shape or similar, and there is the problem that a satisfactory etching profile cannot be obtained. In the case of such an etching profile, coverage of the color filter or electrode film on the upper layer of which the light-shielding film is formed is reduced. Hence air accumulates in the portions of poor coverage of the color filter layer, air bubbles occur within the display panel, or lines are broken in the electrode film. As a result, display defects may occur. As one countermeasure, in Japanese Unexamined Patent Application Publication No. 11-194333, the oxygen flow rate is changed during sputter film deposition, to change the degree of oxidation in the film thickness direction.

However, when using a method in which the flow rate of gas is controlled during film deposition and the degree of oxidation or the degree of nitrification is continuously changed, there have been the following problems. Normally CrOₓ film and CrNₓ film are deposited by reactive sputtering, using a gas mixture in which oxygen or nitrogen gas is added to argon gas. However, there has been the problem that during the limited film deposition time, it is exceedingly difficult to continuously change the flow rate of the oxygen gas or nitrogen gas so as to uniformly change the mixture ratio. That is, when the flow rate of oxygen gas or nitrogen gas is changed continuously, the distribution of gas in the film deposition chamber ceases to be uniform according to the placement of the gas supply opening and similar. In this case, there is unevenness in the distribution of the degree of oxidation or the degree of nitrification within the substrate plane. As a result, etching cannot be performed satisfactorily.

There is also a method in which the mixture ratio of oxygen gas or nitrogen gas with argon gas is changed in steps, to change the degree of oxidation or the degree of nitrification. In this case, the film thickness must be made extremely thin at each step, and so it becomes difficult to secure uniformity of film thickness. Moreover, there is the further problem that the film deposition time becomes extremely long, so that productivity declines. Hence for practical purposes it is difficult to use this method for film deposition.

The inventors of this application performed tests on etching of Cr/CrOₓ multilayer structures using an etching liquid comprising ceric ammonium nitrate and perchloric acid, as described in Japanese Unexamined Patent Application Publication No. 6-250163. Moreover, the liquid composition ratio, etching time and other conditions were variously changed, and evaluations performed. FIG. 10A and FIG. 10B show representative examples of etching profiles at this time. FIG. 10A and FIG. 10B are side views of cross-sectional shapes of light-shielding films which have been etched. In FIG. 10A and FIG. 10B, 1 is the substrate, 2 is a first film comprising CrOₓ, 3 is a second film comprising Cr, and 10 is the light-shielding film. When using etching liquid comprising ceric ammonium nitrate and perchloric acid, as for example shown in FIG. 10A, there is greater etching of the interface between the first film 2 and the second film 3. As a result, the cross-section of the light-shielding film 10 assumes a discontinuous constricted shape. Or, as shown in FIG. 10B, etching of the first film 2 in the lateral direction proceeds more rapidly than for the second film 3, and a reverse-taper shape results. When such etching profiles occur the coverage is reduced, and display quality is degraded.

Further, in Japanese Unexamined Patent Application Publication No. 2004-54228, an etching liquid is used in which the ceric ammonium nitrate content is from 15 to 30 weight percent, and the nitric acid content is from 5 to 8 weight percent. In this case, the angle of the etching end face can be made nearly vertical. However, even when the angle of the etching end face is made vertical, if the light-shielding film is thick the step is sharp, and coverage declines. As a result, display defects have occurred.

In the above-described display devices of the related art, when a light-shielding film having a chromium oxide film is used, a satisfactory etching profile cannot be obtained, and there is the problem of display quality degradation resulting from reduced coverage.

### SUMMARY OF THE INVENTION

This invention was devised in light of the above problems, and has as an object the provision of a substrate with a light-shielding film, a color filter substrate and a display device, and methods of manufacture of these, which enable a satisfactory etching profile even when using a light-shielding film having a chromium oxide film.

According to one aspect of the present invention, there is provided a substrate with a light-shielding film, having a light-shielding film pattern formed on a substrate, the light-shielding film comprises a first film having chromium oxide; and a second film provided on the first film and having chromium; wherein the cross-sectional shape of the pattern of the light-shielding film has a forward-taper shape.

According to another aspect of the present invention, there is provided a method of manufacture of a substrate with a light-shielding film having a light-shielding film pattern formed on a substrate, the method comprising: depositing a first film having chromium oxide and a second film having chromium in order on a substrate, to form a multilayer film; forming a resist pattern on the multilayer film; performing etching of the multilayer film using an etching liquid comprising ceric ammonium nitrate to which nitric acid is added at a concentration of at least 2.5 mol/liter, to form a light-shielding film pattern; and removing the resist pattern.

By means of this invention, a substrate with a light-shielding film, a color filter substrate and a display device, and methods of manufacture of these, which enable a satisfactory etching profile even when using a light-shielding film having a chromium oxide film, can be provided.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a side cross-sectional view showing the configuration of a substrate with a light-shielding film of first embodiment of the invention;

FIG. 2A to FIG. 2F are process cross-sectional views showing processes in the manufacture of a substrate with a light-shielding film of first embodiment of the invention;

FIG. 3 shows the relation between the nitric acid concentration in the etching liquid and the etching cross-section taper angle, in a process of manufacture of a substrate with a light-shielding film of this invention;

FIG. 4A and FIG. 4B schematically show the cross-sectional structure of a pattern;

FIG. 5A and FIG. 5B schematically show the cross-sectional shape of the light-shielding film of a substrate with a light-shielding film of this invention;

FIG. 6A and FIG. 6B schematically show the cross-sectional shape of the light-shielding film when the nitric acid concentration is made high;

FIG. 7 is a side cross-sectional view showing the configuration of a substrate with a light-shielding film of second embodiment of the invention;

FIG. 8A to FIG. 8H are process cross-sectional views showing processes in the manufacture of a substrate with a light-shielding film of second embodiment of the invention;

FIG. 9 is a graph showing the relation between the chromium film thickness and the light transmittance; and,

FIG. 10A and FIG. 10B schematically show the cross-sectional shape of the light-shielding film of a substrate with a light-shielding film of the related art.

### DESCRIPTION OF THE PREFERRED EMBODIMENTS

### First Embodiment

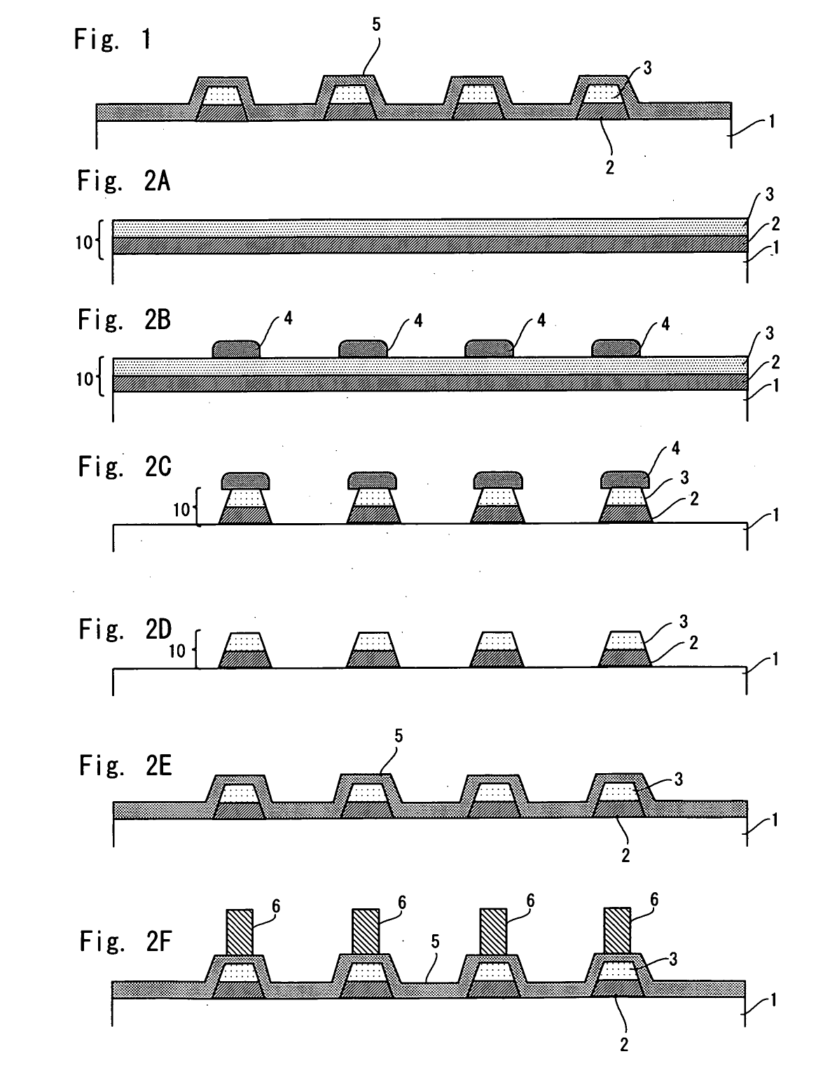

In this embodiment, a substrate with a light-shielding film is explained assuming use in a field-sequential type liquid crystal display device. In FIG. 1, 1 is the substrate, 2 is a first film, 3 is a second film, and 5 is a transparent conductive film.

The substrate 1 comprises, for example, glass or another transparent insulator. The first film 2 is formed on the substrate 1. The first film 2 comprises for example chromium oxide, having low reflectivity. That is, the first film 2 is formed from CrOₓ film (where x is a positive number) with low reflectivity. The degree of oxidation of the first film 2 is substantially constant. The second film 3 is formed on the first film 2. The second film 3 comprises for example metallic chromium, with high opacity. That is, the second film 3 is formed from Cr film with high opacity. The multilayer film comprising the first film 2 and second film 3 serves as the light-shielding film.

The light-shielding film is patterned to form, for example, a lattice shape positioned between pixels. The areas delimited by the light-shielding film are pixels. In other words, the areas between the light-shielding film serve as pixels. The light-shielding film has a smooth forward-taper shape. That is, the cross-sectional shape of the light-shielding film pattern are such that the pattern width is narrower in moving to the surface side of the pattern. In other words, the cross-sectional shape of the light-shielding film pattern is such that the pattern width gradually grows broader in moving toward the substrate side.

A transparent conductive film 5 of ITO is formed on the second film 3. The transparent conductive film 5 is for example formed over the entire substrate so as to cover the light-shielding film. The transparent conductive film 5 serves as an electrode for image display, that is, an opposing electrode placed in opposition to the pixel electrodes. Because the light-shielding film is formed in a tapered shape, coverage of the transparent conductive film 5 can be improved. By this means, the occurrence of broken lines can be prevented, and display quality can be enhanced.

In a field-sequential type liquid crystal display panel, a substrate with a light-shielding film shown in FIG. 1 is placed in opposition to the TFT array substrate. A plurality of lines for image display, and switching elements comprising thin film transistors (TFTs) or similar provided in a matrix shape, are formed on the TFT array substrate. The lines for image display comprise, for example, a plurality of gate lines arranged in parallel, and a plurality of source lines which intersect gate lines with a gate insulating film interposed therebetween. Further, drain electrodes of the thin film transistors are connected to image display electrodes comprising for example ITO or another transparent conductive film. A plurality of image display electrodes are provided in a matrix shape, similarly to the TFTs. Liquid crystals are driven by a voltage applied across the image display electrodes provided on the TFT array substrate and the transparent conductive film 5 formed on the substrate with the light-shielding film. By this means, the amount of light transmitted by the liquid crystal display panel is controlled. An alignment film may be provided on the TFT array substrate or on the substrate with the light-shielding film. In addition, a polarizing film or similar may be affixed to the liquid crystal display panel.

This TFT array substrate is placed in opposition to the substrate with a light-shielding film of FIG. 1, and the two substrates are laminated using a sealing material comprising for example a photosensitive resin. At this time, spacers which maintain a constant gap between the substrates are placed on the substrate with a light-shielding film or on the TFT array substrate. Liquid crystals are then injected into the gap between the substrate with a light-shielding film and the TFT array substrate through a liquid crystal injection opening provided in a portion of the sealing material. By then sealing the liquid crystal injection opening using a hardening resin or similar, the liquid crystal display panel is completed.

Driving circuitry and a backlight unit are mounted on the completed liquid crystal display panel. A backlight unit is a plane-shape light source device which emits light uniformly over an entire plane. The backlight unit comprises, for example, light sources comprising light-emitting diodes of three types, which are red (R), green (G), and blue (B), as well as a light guide plate to guide light from the light sources over the entire plane, and a diffusion sheet, prism sheet, and other optical sheets. Light from the backlight unit is time-divided into red (R), green (G) and blue (B) and used to irradiate the liquid crystal display panel from the rear face. In the liquid crystal display panel, the R, G, B image signals are time-divided and displayed. Specifically, the R, G, B light from the backlight is synchronized with the time-divided R, G, B image signals. Hence during irradiation with R light from the backlight, R image signals are input to the image display electrodes of the liquid crystal display panel. Similarly, during irradiation with G and B light from the backlight, G and B image signals are respectively input to the image display electrodes of the liquid crystal display panel. By this means, the light quantities of R, G, B light can be controlled in color display.

Next, FIG. 2A to FIG. 2F are used to explain processes to manufacture a substrate with a light-shielding film. 2A to FIG. 2F are process cross-sectional views showing processes to manufacture a substrate with a light-shielding film. As shown in FIG. 2A, the first film 2 and second film 3 are deposited continuously on the substrate 1. By this means, the first film 2 and second film 3 are deposited over substantially the entire surface of the substrate 1. The multilayer structure of the first film 2 and second film 3 forms the light-shielding film 10. The first film 2 is a CrOₓ film, that is, is formed from chromium oxide; the second film 3 is a Cr film, that is, is formed from metallic chromium.

In a preferred embodiment, the first film 2 and second film 3 are formed by sputtering. For example, argon gas can be used as the sputtering gas. Metallic chromium (Cr) is used as the target for sputtering. When depositing the first film 2, a gas mixture is used, with oxygen gas added to the argon sputtering gas. That is, the CrOₓ film is deposited by reactive sputtering used a mixture of argon gas and oxygen gas. A CrOₓ film of thickness 50 nm is deposited as the first film 2. The partial pressure ratio of the oxygen gas to the argon gas is 70% during CrOₓ film deposition, and the sputtering gas pressure is adjusted to be 0.5 Pa. By this means, CrOₓ film with a uniform degree of oxidation can be formed.

Next, the sputtering gas is switched to argon gas only in the same film deposition chamber. That is, the supply of oxygen gas is halted. The gas pressure is adjusted to 0.5 Pa, and a chromium film of thickness 120 nm is deposited as the second film 3. In this way, CrOₓ film and Cr film are deposited continuously to form the light-shielding film 10 with a two-layer structure.

Next, as shown in FIG. 2B, a photolithography method is used to form a pattern of photoresist 4 on the second film 3. As a preferred embodiment, a positive photoresist which employs phenolic novolac resin as the main chain is applied to a thickness of 2 μm. Exposure and development are then performed to pattern the photoresist 4. By this means, the configuration shown in FIG. 2B is obtained. The thickness of the photoresist 4 is not limited to 2 μm, but may be approximately 0.5 to 3 μm. The photoresist 4 may be a negative photoresist as well; but in general, positive photoresists have higher resolution, and the photoresist dimensions can be controlled more precisely. Hence it is preferable that a positive photoresist be used.

After forming the photoresist 4, wet etching of the light-shielding film 10 is performed, as in FIG. 2C. As a preferred embodiment, an etching liquid is used in which ceric ammonium nitrate solution with concentration 10 weight percent is mixed with 7 mol/liter nitric acid. Etching by the spray method is performed using this etching liquid. Specifically, etching is performed with the liquid temperature at 35° C., at a spray pressure of 0.15 MPa. The light-shielding film 10 is side-etched from the surface side, so that the patterned width of the light-shielding film 10 is narrower on the surface side.

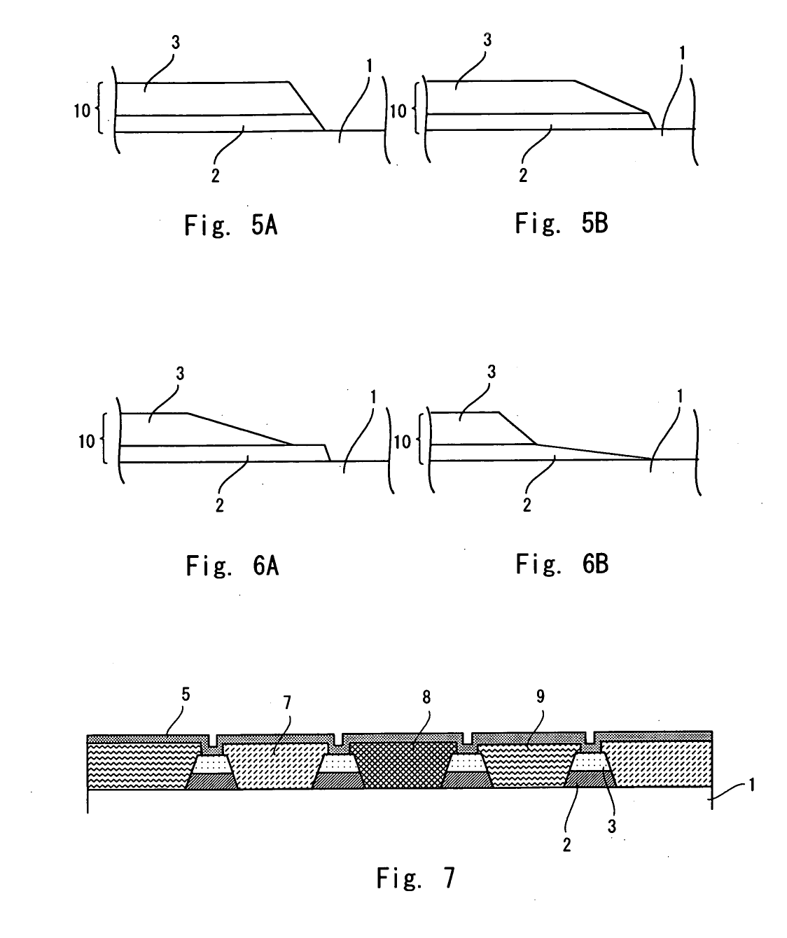

After etching is completed, the photoresist 4 is removed as shown in FIG. 2D. By this means, a pattern of the light-shielding film 10 is formed. The etched cross-sectional shape of the pattern of the light-shielding film 10 formed in this way is a tapered shape. That is, as shown in FIG. 5A, a side view of the pattern of the light-shielding film 10 has a gently sloped shape. FIG. 5A and FIG. 5B are side views of the cross-sectional shape of the light-shielding film 10. The taper angle can be made approximately 24°.

The etching liquid is not limited to that of the above conditions. For example, the concentration of the ceric ammonium nitrate solution on which the etching liquid is based may be from 3 to 25 weight percent. If the concentration of the ceric ammonium nitrate solution is lower than 3 weight percent, the etching rate becomes extremely slow, and productivity declines. If the concentration is higher than 25 weight percent, crystallization of the etching liquid tends to occur due to solvent evaporation and similar. In this case, the etching equipment may be contaminated, or damage may be imparted to the substrate being treated. It is more preferable still that the concentration of the ceric ammonium nitrate be from 5 to 15 weight percent.

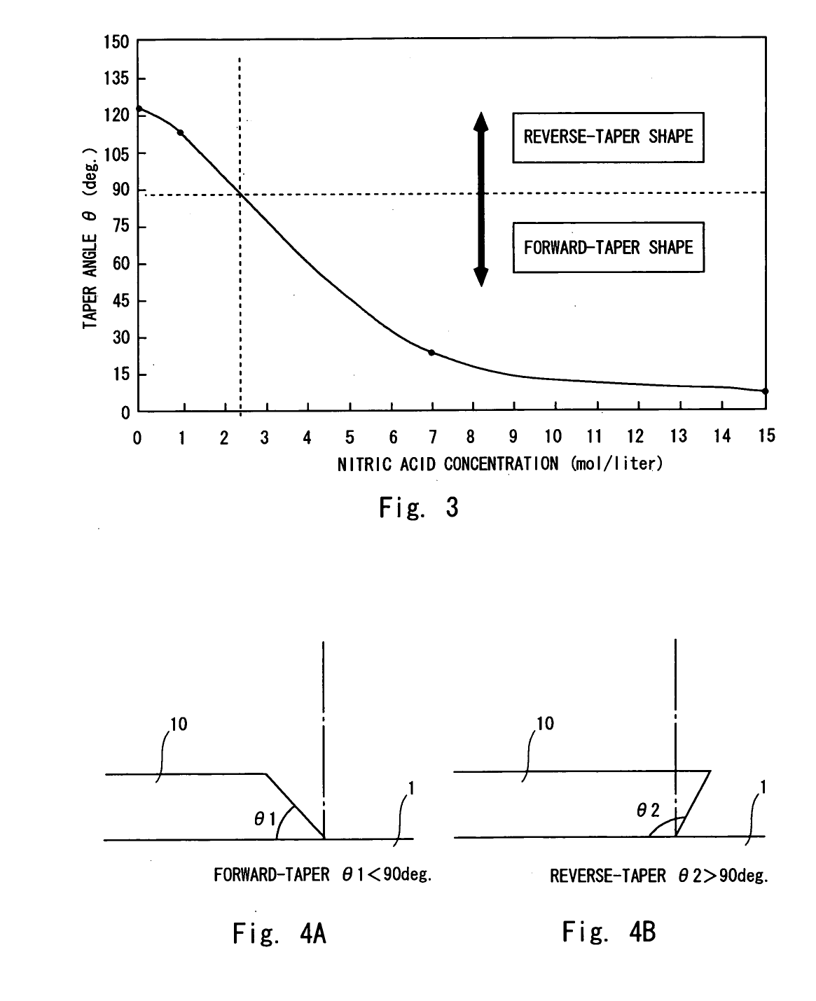

Further, the nitric acid concentration need not be limited to 7 mol/liter. FIG. 3 is a graph showing the change in the taper angle of the etched cross-sectional shape of a multilayer film of CrOₓ film and Cr film, when the nitric acid concentration in the ceric ammonium nitrate solution is varied. Here, a forward-taper shape has an angle θ₁ of the light-shielding film pattern with respect to the substrate surface which is smaller than 90°, as shown in FIG. 4A, while a reverse tape shape has an angle θ₂ of the light-shielding film pattern with respect to the substrate surface which is greater than 90°, as shown in FIG. 4B. In FIG. 4A and FIG. 4B, the pattern cross-sectional structures are shown schematically in order to illustrate the taper angle. If the angle from the substrate surface below the light-shielding film pattern to the side face of the light-shielding film pattern is the taper angle, then when the taper angle is smaller than 90°, the shape is a forward taper, and when greater than 90°, the shape is a reverse taper. That is, the angle from the interface of the light-shielding film 10 with the substrate 1 to the side face of the light-shielding film 10 is the taper angle.

The taper angle changes depending on the nitric acid concentration in the etching liquid. As shown in FIG. 3, when the nitric acid concentration is higher, the taper angle is smaller. That is, as the nitric acid concentration is made higher, the side face shape of the light-shielding film pattern grows more gradual. In order to prevent breaking of the transparent electrode film formed on the top layer, it is preferable that the taper angle be substantially 90° or that the taper be a forward-taper shape. From this, it is preferable that the nitric acid concentration be 2.5 mol/liter or higher.

When the nitric acid concentration is increased, the taper angle becomes smaller; but the overall etching rate declines, and productivity is lowered. Further, the CrOₓ film and Cr film taper angle differs. For example, when the nitric acid concentration is 14 mol/liter, the Cr film taper angle is seen to be reduced compared with the taper angle of CrOₓ film, as shown in FIG. 5B. That is, the side face of the Cr film is no longer parallel to the side face of the CrOₓ film. This is because as the nitric acid concentration is raised, permeation of the etching liquid is intensified at the interface of the Cr film and the pattern of the photoresist 4, and etching liquid which has permeated into the interface proceeds to etch while removing the photoresist 4 on the interface with the chromium film.

When the nitric acid concentration exceeds 14 mol/liter, etching of the chromium film proceeds still further, and as shown in FIG. 6A, the edge of the Cr film on the side of the lower face also recedes from the edge on the upper-face side of the CrOₓ film. That is, the Cr film on the pattern edge of the CrOₓ film is etched, and the edge of the Cr film on the side of the CrOₓ film no longer coincides with the position of the edge of the CrOₓ film on the Cr film side. As etching proceeds further, a shape such as that of FIG. 6B may also occur. That is, the taper angle of the CrOₓ film becomes smaller than the taper angle of the Cr film.

When the shape becomes as shown in FIG. 6A or FIG. 6B, scattering in the taper portion becomes prominent, and dimensional control is difficult. Further, the high-opacity second film 3 is no longer formed on the edge portion of the first film 2, which is the low-reflectivity film. Hence when intense transmitted light is incident, the light passes through the first film 2, which is the low-reflectivity film, and transmitted light leaks through. As a result, sufficient light shielding characteristics cannot be obtained at the edge portions of the pattern of the light-shielding film 10, and the contrast ratio of displayed images declines. For the above reasons, it is preferable that the nitric acid concentration be 14 mol/liter or lower. Thus it is preferable that the concentration of nitric acid with respect to the ceric ammonium nitrate which is the base be 2.5 mol/liter or greater and 14 mol/liter or lower.

The temperature of the etching liquid is not limited to 35° C. It is preferable that the liquid temperature be for example 20 to 50° C., and still more preferable that the temperature be 23 to 40° C. When the temperature is 20° C. or lower, the etching rate is extremely low, and productivity declines. As the liquid temperature rises the etching rate increases, and productivity improves; but upon exceeding 50° C., fluctuations in the liquid composition due to evaporation become pronounced. Hence liquid replacement must be performed frequently in order to maintain a stable process. For the above reasons, a liquid temperature of 20 to 50° C. is preferable.

It is preferable that the spray method be used for etching. The spray pressure is not limited to 0.15 MPa, but a pressure in the range 0.03 MPa to 0.3 MPa is preferable. When using a dipping (immersion) method or the spray method at a spray pressure lower than 0.03 MPa, the in-plane etching uniformity is degraded, and dispersion in pattern dimensions and other unevenness tend to occur. On the other hand, at 0.3 MPa and higher, substrate cracking may occur, or the photoresist 4 may be peeled, so that broken lines result. It is still more preferable that the spray pressure be between 0.05 MPa and 0.2 MPa.

As shown in FIG. 2E, a transparent conductive film 5 is formed on the light-shielding film 10. As a preferred embodiment, sputtering is used to form an ITO film in which indium oxide and tin oxide are intermixed, to form the transparent conductive film 5. The transparent conductive film 5 is formed over substantially the entirety of the substrate 1. By this means, the substrate with a light-shielding film of FIG. 1 is completed. The transparent conductive film 5 can be patterned to a desired shape using a photolithography method as necessary.

Further, a pattern of spacers 6 may be formed on the transparent conductive film 5, as shown in FIG. 2F. The column-shaped spacers 6 are formed on the pattern of the light-shielding film 10. Of course, when an alignment film is formed, the spacers 6 are formed on the alignment film. For example, a photosensitive resin comprising an organic acrylic resin can applied, and a photolithography method used to expose and develop the film to form a pattern of spacers 6.

In a field-sequential type liquid crystal display device, the substrate with a light-shielding film shown in FIG. 1 is used as the opposing substrate which is placed in opposition to the TFT array substrate. At this time, the image display electrodes are positioned so as to correspond to the pattern of the light-shielding film 10. The TFT array substrate and the substrate with a light-shielding film are then laminated together, with a constant gap provided therebetween. The TFT array substrate and the substrate with a light-shielding film are laminated using a sealing material. Then, after injecting liquid crystals between the substrates, sealing is performed. In this way, the liquid crystal display panel is completed. Driving circuitry and a backlight are also mounted. By this means, a field-sequential type color liquid crystal display device is completed.

### Second Embodiment

The configuration of a substrate with a light-shielding film of this embodiment is explained using FIG. 7. FIG. 7 is a side cross-sectional view showing the configuration of the substrate with a light-shielding film. In this embodiment, an example of application of this invention to a color filter substrate, which is an opposing substrate in an ordinary liquid crystal display device, is explained. Hence explanations of portions similar to first embodiment are omitted. 7 is an R color filter layer, 8 is a G color filter layer, and 9 is a B color filter layer. That is, white light incident on the rear surface of the liquid crystal display panel from the backlight unit, or external light incident from the viewing side and reflected by a reflecting electrode of the image display portion, passes through the color filter layers to effect color display.

As shown in FIG. 7, the first film 2 and second film 3 which form the light-shielding film are layered on the substrate. The R color filter layer 7, G color filter layer 8, and B color filter layer 9 are provided between adjacent light-shielding film pattern portions. The areas in which these color filter layers 7, 8, 9 are provided serve as pixels. A pixel in which the R color filter layer 7 is provided is positioned adjacent to the left of a pixel in which the G color filter layer 8 is provided. A pixel in which the B color filter layer 9 is provided is positioned adjacent to the right of a pixel in which the G color filter layer 8 is provided. That is, the R color filter layer 7, G color filter layer 8, and B color filter layer 9 are arranged in order. A portion of the color filter layers 7, 8, 9 is formed on the light-shielding film 10. That is, the color filter layers 7, 8, 9 and the light-shielding film 10 are formed so as to partially overlap. A transparent conductive film 5 is provided on the second film 3 and on the R color filter layer 7, G color filter layer 8, and B color filter layer 9. The transparent conductive film 5 is provided so as to cover the light-shielding film and color filter layers. In this embodiment, the color filter layers 7, 8, 9 are formed on top of the side face of the tapered light-shielding film 10, so that coverage can be improved.

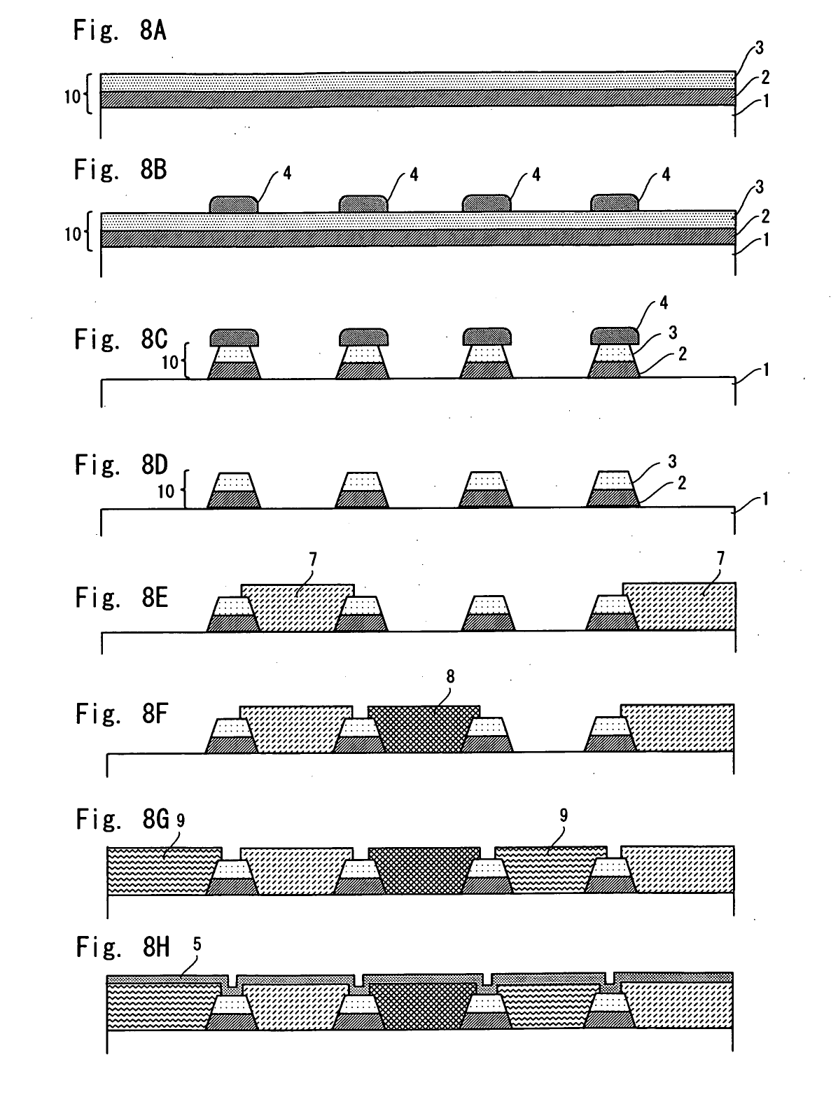

Next, FIG. 8A to FIG. 8H are used to explain process to manufacture the color filter substrate of this embodiment. FIG. 8A to FIG. 8H are process cross-sectional views showing processes to manufacture the color filter substrate of this embodiment. Because the processes of FIG. 8A through FIG. 8D are similar to those of first embodiment, a detailed explanation is omitted.

As shown in FIG. 8A, the first film 2 and second film 3 are deposited continuously to form the light-shielding film 10. For example, the first film 2 is a CrOₓ film, and the second film 3 is a Cr film. And as shown in FIG. 8B, a pattern of photoresist 4 is formed on the light-shielding film 10. Further, as shown in FIG. 8C, the first film 2 and second film 3 are continuously etched, to pattern the light-shielding film 10. After the etching is completed, the photoresist 4 is removed. By this means, the configuration of FIG. 8D is obtained. The etching process is performed similarly to first embodiment. That is, as the etching liquid used in this embodiment, a ceric ammonium nitrate solution mixed with nitric acid can be used. The concentrations are similar to those of first embodiment. By this means, a substrate with a light-shielding film 10 can be formed. The etched cross-sectional shape of the pattern of the light-shielding film 10 formed in this way, is a tapered shape like that shown in FIG. 5A and FIG. 5B.

After forming the light-shielding film 10, the R color filter layer 7 is patterned to the desired shape. As a preferred embodiment, a color resist, which is a photosensitive resin into which red pigment is mixed, is applied to a thickness of approximately 2.0 μm. Then a photolithography method is used for exposure, followed by development. By this means, the R color filter layer 7 is formed between the pattern portions of the light-shielding film 10. Thereafter, as post-exposure processing, light which intermixes the g line, h line, and i line is used in irradiation, and post-exposure baking is performed at a temperature of approximately 220° C. By this means, the R color filter layer 7 is patterned as shown in FIG. 8E.

After forming the R color filter layer 7, the G color filter layer 8 is patterned to the desired shape. Here, the color resist, which is a photosensitive resin with a green pigment intermixed, is applied to a thickness of approximately 2.0 μm. Then, similarly to the R color filter layer 7, a photolithography method is used for exposure, followed by development. Then, as post-exposure processing, light which intermixes the g line, h line, and i line is used in irradiation, and post-exposure baking is performed at a temperature of approximately 220° C. By this means, the G color filter layer 8 is patterned as shown in FIG. 8F.

Then, the B color filter layer 9 is patterned to the desired shape. Here, the color resist, which is a photosensitive resin with a blue pigment intermixed, is applied to a thickness of approximately 2.0 μm. Then, similarly to the R color filter layer 7, a photolithography method is used for exposure, followed by development. Then, as post-exposure processing, light which intermixes the g line, h line, and i line is used in irradiation, and post-exposure baking is performed at a temperature of approximately 220° C. By this means, the B color filter layer 9 is patterned as shown in FIG. 8G.

Next, after forming the three color filter layers, the transparent conductive film 5 serving as the opposing electrode is formed. As a preferred embodiment, an ITO film, in which indium oxide and tin oxide are intermixed, is deposited as the transparent conductive film 5. The ITO film can for example be deposited by sputtering. By this means, the color filter substrate is completed, as shown in FIG. 8H.

In the above embodiments, an ITO film was used as the transparent conductive film 5, but other films may be used. For example, films which are oxides of single metal elements such as indium oxide (In₂O₃), tin oxide (SnO₂), and zinc oxide (ZnO), as well as films comprising a mixture of oxides combining these, can also be used. In particular, in second embodiment there exist color filter layers comprising photosensitive resins on the film deposition surface of the transparent conductive film 5. When depositing the ITO film, the effect of the plasma during sputtering may cause the decomposition of resin comprised by the color filter layers and the release of decomposition gases. Further, water contained in the resin comprised by the color filter layers may be released. Such water and decomposition gas components may cause degradation of the light transmittance and the resistivity and other electrical characteristics of the ITO film. In such cases, it is preferable that an ITZO film, in which ITO is further combined with zinc oxide, or that an oxide film combining indium oxide and zinc oxide (IZO), be used. By this means, the effect on characteristics of water and decomposition gas components emitted from color filter layers can be reduced compared with an ITO film. The transparent conductive film 5 may also be patterned to a desired shape using normal photolithography methods, where necessary.

As shown in FIG. 10A and FIG. 10B, the cross-sectional shape of the pattern of a light-shielding film 10 formed by a method of the related art is constricted, or assumes a reverse-taper shape. Consequently the color filter layers are not packed into the pattern edge portions of the light-shielding film 10, and gaps may be formed. For example, when a gap portion is formed on the light-shielding film 10 of the color filter substrate in a liquid crystal display panel, there are the problems that air bubbles are formed in the liquid crystal display panel, and display defects occur. However, by using the etching liquid described in first embodiment, the pattern shape of the light-shielding film 10 can be made a substantially forward-taper shape, as shown in FIG. 5A or FIG. 5B. Hence the coverage of the color filter layers can be made satisfactory, and the occurrence of display defects can be prevented.

In second embodiment, the method of forming the photoresist 4 was explained as a method of spin application of color resists into which pigments are intermixed as coloring materials; but other methods may be used. For example, a film transfer method can be used, in which a photosensitive resin into which a coloring material is intermixed is formed into a film, and this film is transferred onto (affixed to) the substrate. The transferred film serving as the color filter layer can be processed to form a desired pattern using a photolithography method, similarly to second embodiment.

By means of this film transfer method, a color filter layer can be formed simply by installing equipment to transfer film. Hence compared with conventional spin application methods, the cost of equipment installation can be reduced. Moreover, there is no scattering of excess color resist as in conventional spin application methods, so that the efficiency of utilization of color resist material can be improved. Consequently, material costs can be reduced.

When the etched cross-sectional shape is constricted or assumes a reverse-taper shape as in a light-shielding film 10 formed by conventional methods, if the film transfer method is used the coverage is degraded even more than when using a spin application method. Hence by using this invention, even greater advantages can be obtained.

Further, in addition to the above-described methods, an inkjet method can also be used to form the color filter layers 7, 8, 9. In this case, during formation using the color filter materials, the color filter layers can be formed into the desired pattern directly. As a result, there is the advantage that patterning using a photolithography method is unnecessary. In the case of an inkjet method also, by applying this invention, the advantage of improved coverage, similar to the case of a spin application method, is obtained.

In an ordinary liquid crystal display panel, a color filter substrate completed by means of the above processes is used as the opposing substrate. That is, the color filter substrate shown in FIG. 7 and a TFT array substrate are placed in opposition and laminated. Prior to the lamination process, spacers may be provided on the color filter substrate to maintain a constant gap between the substrates. Then, liquid crystals are injected into the gap between the substrate with a light-shielding film and the TFT array substrate from a liquid crystal injection opening provided in a portion of the sealing material. When the liquid crystal injection opening is sealed using a hardening resin or similar, the liquid crystal display panel is completed. Driving circuitry and a backlight unit are mounted on the completed liquid crystal display panel. By this means, a liquid crystal display device is completed. In this embodiment, the color filter layers were red, green and blue; but others may be used. The colors and color types of the color filter may be chosen arbitrarily according to the display color characteristics required.

When fabricating the above-described liquid crystal display panel, for example an organic resin material may be patterned to form a plurality of spacers, in order to precisely control the constant gap with the TFT array substrate placed in opposition. For example, a photosensitive resin film comprising an organic acrylic resin may be applied, an ordinary photolithography method used in exposure, and development performed to form the spacers.

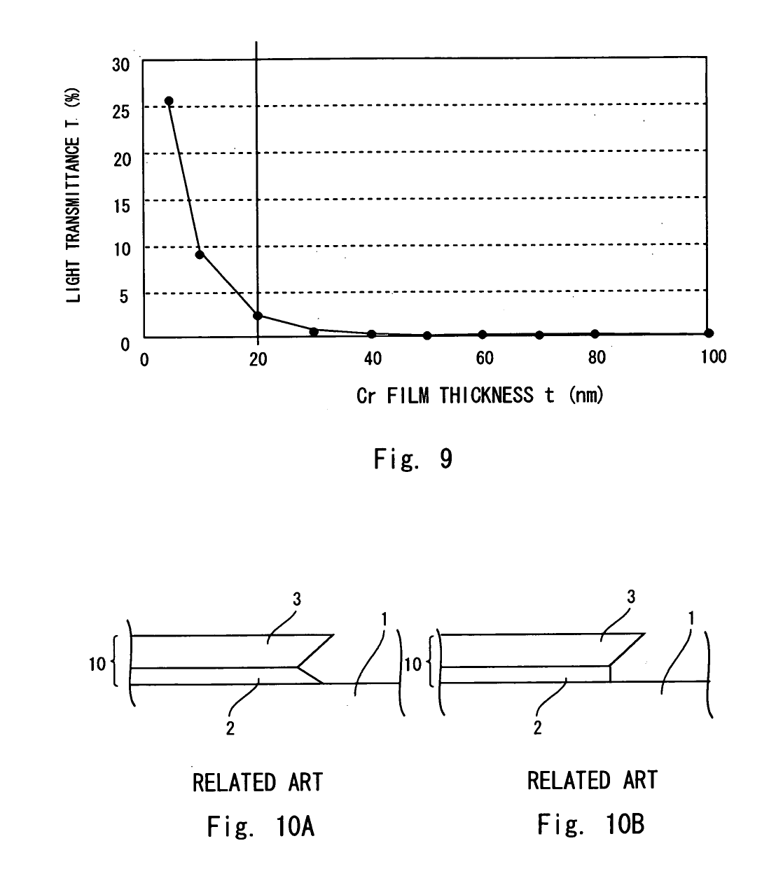

In the above first and second embodiments, a CrOₓ film of thickness 50 nm was formed as the first film 2, but other films may be used. The first film 2 may for example be 20 nm or greater and 100 nm or less in thickness. FIG. 9 shows the relation between the film thickness of the Cr film and the light transmittance. Here, the results of measurements of the light transmittance using light of wavelength 550 nm are shown. As seen in FIG. 9, the light transmittance of the Cr film increases rapidly from a film thickness of less than 20 nm. That is, when the thickness of the CrOₓ film which is the first film 2 decreases to under 20 nm, light incident on the glass substrate passes through the CrOₓ film and is reflected at the surface of the Cr film which is a light-shielding film. Hence this reflected light is superposed on the displayed image, and so images of objects outside the liquid crystal display panel appear superposed on the displayed image, as if in a mirror. Hence the display quality is degraded. If the CrOₓ film thickness is 20 nm or greater, then the light transmittance can be held to 3% or lower. Hence light can be adequately absorbed by the CrOₓ film, and the appearance of images of objects outside the panel in the displayed image can be prevented.

On the other hand, when performing reactive sputtering using argon gas plus oxygen gas, the film deposition rate is slow, and so if the thickness of the CrOₓ which is the first film 2 is made 100 nm or greater, the film deposition time becomes long, and productivity declines. Hence it is preferable that the CrOₓ film thickness be 100 nm or less. Hence it is preferable that the thickness of the first film 2, which is a low-reflectivity CrOₓ film, be 20 nm or greater and 100 nm or less. Moreover, in consideration of the optical characteristic (optical reflectivity, light transmittance) margins as well as productivity and production yields, it is preferable that the thickness be 40 nm or greater and 60 nm or less.

Further, in first and second embodiments the second film 3, comprising a Cr film of thickness 120 nm, is deposited continuously following the first film 2; but other methods may be used. For example, a Cr film of thickness 20 nm or greater and 400 nm or less can be used as the second film 3. As shown in FIG. 9, the light transmittance of the Cr film begins to increase rapidly at a film thickness of less than 20 nm. That is, when the thickness of the Cr film, which is the light-shielding layer used to prevent light transmission, is less than 20 nm, there is the possibility that light cannot be adequately blocked. Hence the original function of the film of shielding light is effectively lost, and light leakage and other display defects occur.

Further, if the thickness of the Cr film is 400 nm or greater, film stresses are increased, and considerable bowing of the substrate 1 occurs. As a result, in subsequent photolithography processes the precision of taper patterns is worsened, and transport problems and similar may result in problems which preclude processing, the Cr film may be separated, or other problems may occur. As a result, lowered production yields and worsened reliability may ensue. In general, stresses in a Cr film deposited on a glass substrate are 1000 MPa or higher, and are larger than the stresses in ordinary metal films formed by sputtering (for example, stresses are approximately 100 to 300 MPa in Al film, and are approximately 100 to 500 MPa in Mo film). Consequently if the Cr film thickness is made 400 nm or greater, the total stress in the deposited chromium film becomes large, and as a result the problems described above may occur. Hence it is preferable that the thickness of the Cr film which as the second film 3 is 20 nm or greater and 400 nm or less, and still more preferable, in light of optical characteristic margins and production yields, that the thickness be 100 nm or greater and 150 nm or less.

Further, the second film 3 is not limited to Cr film, but may be CrNₓ film (where x is a positive number) with nitrogen added to Cr. CrNₓ film also be deposited by reactive sputtering, using a gas mixture in which nitrogen gas is added to argon gas. By using CrNₓ as the second film 3, film stresses can be made small. It is preferable that the thickness of the CrNₓ film be the same as the thickness of the above-described Cr film, equal to or greater than 20 nm and equal to or less than 400 nm. Further, in the case of a CrNₓ film, crystal grains can be made smaller than in a Cr film, so that a crystal structure with a finer texture can be obtained. Hence compared with Cr film, light-shielding characteristics equivalent to those of Cr film can be obtained at a smaller film thickness. The film thickness in an actual implementation should be determined according to the light-shielding characteristics required. Even when using CrNₓ film as the second film 3, by applying this invention, the cross-sectional shape of the light-shielding film 10 can be processed to a forward-taper shape. By this means, advantageous results similar to those of first and second embodiments can be obtained.

In the above explanations, a substrate with a light-shielding film used in a liquid crystal display device was explained; however, this invention can also be used for substrates with a light-shielding film employed in devices other than a liquid crystal display device. For example, use in an electroluminescence (EL) display device, in a plasma display panel, and in other flat panel displays is possible. Further, this invention may also be applied to substrates with a light-shielding film and to color filter substrates used in devices other than display devices.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A substrate with a light-shielding film, having a light-shielding film pattern formed on a substrate, the light-shielding film comprises:
a first film having chromium oxide; and
a second film provided on the first film and having chromium;
wherein the cross-sectional shape of the pattern of the light-shielding film has a forward-taper shape.

2. The substrate with a light-shielding film according to claim 1, wherein the second film has chromium nitride.

3. The substrate with a light-shielding film according to claim 1, wherein the thickness of the first film is 20 nm or greater and 100 nm or less, and the thickness of the second film is 20 nm or greater and 400 nm or less.

4. The substrate with a light-shielding film according to claim 1, wherein a transparent conductive film is formed on the light-shielding film.

5. A color filter substrate, comprising:
the substrate with a light-shielding film according to claim 1; and,
a color filter layer, formed between the pattern portions of the light-shielding film.

6. A display device, comprising the substrate with a light-shielding film according to claim 1.

7. A method of manufacture of a substrate with a light-shielding film having a light-shielding film pattern formed on a substrate, the method comprising:
depositing a first film having chromium oxide and a second film having chromium in order on a substrate, to form a multilayer film;
forming a resist pattern on the multilayer film;
performing etching of the multilayer film using an etching liquid comprising ceric ammonium nitrate to which nitric acid is added at a concentration of at least 2.5 mol/liter, to form a light-shielding film pattern; and
removing the resist pattern.

8. The method of manufacture of a substrate with a light-shielding film according to claim 7, wherein the second film has chromium nitride.

9. The method of manufacture of a substrate with a light-shielding film according to claim 7, wherein the first film is formed to a thickness of 20 nm or greater and 100 nm or less, and the second film is formed to a thickness of 20 nm or greater and 400 nm or less.

10. The method of manufacture of a substrate with a light-shielding film according to claim 7, further comprising:
forming a transparent conductive film on the light-shielding film pattern after removing the resist pattern.

11. The method of manufacture of a substrate with a light-shielding film according to claim 7, wherein the nitric acid concentration in the etching liquid is 14 mol/liter or less.

12. The method of manufacture of a substrate with a light-shielding film according to claim 7, wherein etching is performed using an etching liquid in which the nitric acid is mixed with a ceric ammonium nitrate solution of concentration 3 weight percent or more and 25 weight percent or less.

13. A method of manufacture of a color filter substrate, comprising:
manufacturing a substrate with a light-shielding film using the method of manufacture of a substrate with a light-shielding film according to claim 7; and
forming a color filter layer between the pattern portions of the light-shielding film formed on the substrate with the light-shielding film.
